(19) United States
(12) Patent Application Publication
(10) Pub. No.: US 2023/0188871 A1
(43) Pub. Date: Jun. 15, 2023

(54) SOLID-STATE IMAGING DEVICE, DRIVING METHOD, AND ELECTRONIC DEVICE

(71) Applicant: SONY SEMICONDUCTOR SOLUTIONS CORPORATION, KANAGAWA (JP)

(72) Inventors: KENICHI ARAKAWA, KANAGAWA (JP); HIROKI UI, TOKYO (JP)

(21) Appl. No.: 16/348,984

(22) PCT Filed: Nov. 21, 2017
(86) PCT No.: PCT/JP2017/041757

§ 371 Date: Aug. 28, 2019

(30) Foreign Application Priority Data
Dec. 5, 2016 (JP) 2016-236015

(51) Int. Cl. H04N 25/78; H04N 25/77; H04N 25/779

(52) U.S. Cl. CPC H04N 25/78; H04N 25/77; H04N 25/779

(57) ABSTRACT

The present technology relates to a solid-state imaging device, a driving method, and an electronic device capable of suppressing leakage of charge from PD to FD. In a solid-state imaging device according to an aspect of the present technology, in a case where the charge is read out from a selected photoelectric conversion unit as a charge readout target out of the plurality of photoelectric conversion units sharing the shared holding unit to the shared holding unit, a drive control unit applies a first pulse to the readout unit that corresponds to the selected photoelectric conversion unit, and applies a second pulse having a polarity opposite to a polarity of the first pulse and having a pulse period overlapping with at least a portion of the pulse period of the first pulse, to a site coming into a capacitive coupling state with the shared holding unit. The present technology is applicable to a back-illumination CMOS image sensor, for example.

### TECHNICAL FIELD

The present technology relates to a solid-state imaging device, a driving method, and an electronic device, and in particular, relates to a solid-state imaging device, a driving method, and an electronic device suitable for use in a case where a plurality of pixels share floating diffusion (FD).

### BACKGROUND ART

Conventionally, a configuration of a solid-state imaging device in which FD is shared by a plurality of pixels is known (refer to Patent Document 1, for example).

FIG. 1 is an equivalent circuit diagram illustrating an example of a configuration of a solid-state imaging device in which FD is shared by two pixels. FIG. 2 is a top view illustrating an example of a configuration of a solid-state imaging device in which FD is shared by four pixels arranged in a Bayer array.

The solid-state imaging device illustrated in FIG. 1 includes a PD 11-1 and a PD 11-2, a readout gate 12-1 and a readout gate 12-2, FD 13, an amplifier gate 14, a selection gate 15, and a reset gate 17. Furthermore, the solid-state imaging device includes a drive control unit (not illustrated) that applies voltage needed to drive each of the readout gates 12, the selection gate 15, and the reset gate 17.

The PD 11-1 and PD 11-2 generate and store charge by photoelectric conversion corresponding to the incident light. The readout gate 12-1 reads the charge stored in the PD 11-1 to the FD 13. The similar applies to the readout gate 12-2. The FD 13 holds the charge read out from the PD 11-1 or the like. The amplifier gate 14 turns the charge held in the FD 13 to a voltage signal and outputs the signal to the selection gate 15. The selection gate 15 outputs the voltage signal input from the amplifier gate 14 to the downstream via a signal line 16. The reset gate 17 discharge (resets) the charge held in the FD 13.

In the solid-state imaging device of FIG. 1, in the case of reading out the charge generated and stored by the photoelectric conversion in the PD 11-1, first, the selection gate 15 is turned on, and then, the reset gate 17 is turned on to reset the FD 13. Thereafter, the readout gate 12-1 is turned on (potential is raised) to read the charge from the PD 11-1 to the FD 13. Subsequently, the readout gate 12-1 is turned off, and the charge is held in the FD 13. Finally, the charge held in the FD 13 is output as a voltage signal from the signal line 16 via the amplifier gate 14 to the downstream. Thereafter, the selection gate 15 is turned off.

Next, in the case of reading out the charge generated and stored by the photoelectric conversion in the PD 11-2, first, the selection gate 15 is turned on, and then, the reset gate 17 is turned on to reset the FD 13. Thereafter, the readout gate 12-2 is turned on to read the charge from the PD 11-2 to the FD 13. Subsequently, the readout gate 12-2 is turned off, and the charge is held in the FD 13. Finally, the charge held in the FD 13 is output as a voltage signal from the signal line 16 via the amplifier gate 14 to the downstream. Thereafter, the selection gate 15 is turned off.

Note that all or a part of excess charge (blooming of charge exceeding saturation of pixel) generated in the PD 11-1 during an exposure period flow out to the FD 13 via the readout gate 12-1 and is then discharged via the reset gate 17. Similarly, the excess charge occurring in the PD 11-2 flows out to the FD 13 via the readout gate 12-2 and is then discharged via the reset gate 17. Therefore, in the solid-state imaging device of FIG. 1, the charge readout path and the excess charge discharge path both pass through the FD 13.

### CITATION LIST

### Patent Document

Patent Document 1: Japanese Patent Application Laid-Open No. 2015-26938

### SUMMARY OF THE INVENTION

### Problems to be Solved by the Invention

In a case where both the charge readout path and the excess charge discharge path pass through the FD 13 as in the configuration illustrated in FIG. 1, the following problems can occur.

FIG. 3 includes a cross-sectional views (A in FIG. 3) of the PD 11-1 and the PD 11-2, the readout gates 12-1 and 12-2, and the FD 13, and includes a view indicating potential of these (B in FIG. 3), among the configuration illustrated in FIG. 1. Note that FIG. 3 illustrate a case where charge is read out from the PD 11-1, in which the PD 11-1 is denoted as a selected pixel, and the PD 11-2 from which the charge has been read out is denoted as a non-selected pixel. Hereinafter, the PD 11-1 and the PD 11-2 will be simply referred to as the PD 11 in a case where it is not necessary to distinguish between them. The similar applies to the readout gates 12-1 and 12-2.

FIG. 4 illustrates a conventional applied voltage to the readout gate 12 of the selected pixel and the non-selected pixel. Note that in FIG. 4, TRG 1 represents the applied voltage to the readout gate 12 of the selected pixel, while TRG 2 to TRG 4 represent the applied voltages to the readout gate 12 of the non-selected pixel.

Normally, an L bias of a negative voltage is applied to the readout gate 12 during the exposure period. The portion under the readout gate 12 is subjected to the implant tuning so as to have a potential slightly higher than a reference potential (GND) to allow excess charge generated in the PD 11 to be discharged even in a state where the L bias of the negative voltage is applied.

Additionally, together with application of the negative voltage to the readout gate 12, holes is induced to an interface and is kept in a pinning state having a stable potential. This enables the holes to be filled under the readout gate 12 to prevent depletion of the interface, so as to reduce dark current at the readout gate 12.

Meanwhile, as illustrated in A of FIG. 3, mutual capacitive coupling is occurring between the shared FD 13 and the readout gates 12-1 and 12-2. Therefore, in order to read out charge from the PD 11-1 of the selected pixel, the readout gate 12-1 of the selected pixel is turned on (switching applied voltage from L level to H level) while the readout gate 12-2 of the non-selected pixel is turned off (applied voltage is kept as it is), as illustrated in A of FIG. 4. Unfortunately, however, in conjunction with the switching of the applied voltage to the readout gate 12-1 of the selected pixel to the H level, the applied voltages to the FD 13 and the readout gate 12-2 in which capacitive coupling is occurring also fluctuate from a direction of the steady L level to a direction of the H level.

In a case where the applied voltage to the readout gate 12-2 of the non-selected pixel fluctuates in a direction of H level, the holes at the interface below the readout gate 12-2 would be eliminated. This leads to collapse of the pinning state, and the potential under the readout gate 12-2 is raised. At this time, if the PD 11-2 is at the saturation level, a part of the saturated charge would leak into the FD 13.

For example, as illustrated in FIG. 2, in order to read out charge from the PD 11 of one selected pixel out of four pixels in a case where the four pixels of the Bayer array share the FD 13, the readout gate 12 of the selected pixel is turned on (applied voltage is switched from the L level to the H level), while the readout gates 12 of the other three non-selected pixels are turned off (applied voltage is kept as it is), as illustrated in B of FIG. 4. In this case as well, the readout gates 12-2 to 12-4 of the FD 13 and the three non-selected pixels also fluctuate from a direction of the steady L level to a direction of the H level and the potential is raised. At this time, when the PD 11 of the non-selected pixels is at the saturated level, a part of the saturated charge would leak into the FD 13.

FIG. 5 illustrates conventional photoelectric conversion characteristics in a case where the FD 13 is shared by four pixels of the Bayer array. Note that in A of FIG. 5, the horizontal axis represents exposure time under the constant light intensity out of light intensity and exposure time, which determine the exposure amount, and the vertical axis represents the signal amount. In B of FIG. 5, the horizontal axis represents light intensity under the constant exposure time out of light intensity and exposure time, which determine the exposure amount, while the vertical axis represents signal amount.

For example, in a case where Gr is defined as a selected pixel among four pixels Gr, R, B, and Gb, and when the selected pixel Gr and the non-selected pixel Gb are at the saturation level, a part of the saturated charge of the non-selected pixel Gb would leak into the FD 13. This would result in occurrence of a difference between signal values of Gr and Gb which would have matched, leading to an increase in the signal amount of the selected pixel Gr than a proper amount.

Furthermore, for example, in a case where B is defined as a selected pixel among the four pixels Gr, R, B, Gb, and when the selected pixel Gb is at the saturation level, a part of the saturated charge of the non-selected pixel Gb would leak into the FD 13, degrading the linearity of the signal amount of the selected pixel B.

As in the above example, in a case where the non-selected pixels are saturated, and when the charge is read out from the selected pixel, a part of the saturated charge of the non-selected pixels would leak into the FD 13, and this causes deviation of the signal amount of the pixel from an original value or causes loss of linearity, leading to degradation of image quality.

The present technology has been made in view of such a situation, and aims to suppress leakage of charge from PD to FD that can be induced from capacitive coupling between the FD and the readout gate in a case where FD is shared by a plurality of pixels.

### Solutions to Problems

A solid-state imaging device according to a first aspect of the present technology includes: a photoelectric conversion unit that generates charge by photoelectric conversion corresponding to incident light and temporarily stores the generated charge; a readout unit provided in each of the photoelectric conversion units and configured to read out the charge temporarily stored in the photoelectric conversion unit; a drive control unit that applies a drive pulse to the readout unit; and a shared holding unit shared by a plurality of the photoelectric conversion units and configured to hold the charge read out from the photoelectric conversion unit by the readout unit, in which in a case where the charge is read out from a selected photoelectric conversion unit as a charge readout target out of the plurality of photoelectric conversion units sharing the shared holding unit to the shared holding unit, the drive control unit applies a first pulse to the readout unit that corresponds to the selected photoelectric conversion unit, and applies a second pulse having a polarity opposite to a polarity of the first pulse and having a pulse period overlapping with at least a portion of a pulse period of the first pulse, to a site coming into a capacitive coupling state with the shared holding unit.

The solid-state imaging device according to the first aspect of the present technology can further include: a reset unit that sets the shared holding unit to a predetermined voltage; and a signal line that transmits signal charge of the shared holding unit as a signal voltage, in which in a case where the charge is read out from the selected photoelectric conversion unit out of the plurality of photoelectric conversion units sharing the shared holding unit to the shared holding unit, the drive control unit can apply the first pulse to the readout unit that corresponds to the selected photoelectric conversion unit, and the drive control unit can apply the second pulse to at least one of the readout unit that corresponds to the one except for the selected photoelectric conversion unit out of the plurality of photoelectric conversion units sharing the shared holding unit, the reset unit, or the signal line.

The second pulse can have a polarity opposite to a polarity of the first pulse and can have a pulse period matching the pulse period of the first pulse.

The second pulse can have a polarity opposite to a polarity of the first pulse and can have a pulse period including a pulse period of the first pulse.

The second pulse can have a polarity opposite to a polarity of the first pulse and can have a pulse period including a period from a P-phase data determination timing to a D-phase data determination timing.

The shared holding unit can be shared by a plurality of photoelectric conversion units having different exposure environments.

In a case of the plurality of photoelectric conversion units having different exposure environments, the charge can sequentially be read out to the shared holding unit in order from the photoelectric conversion unit having the greater exposure amount.

As a first aspect of the present technology, a method of driving a solid-state imaging device including a photoelectric conversion unit that generates charge by photoelectric conversion corresponding to incident light and temporarily stores the generated charge, a readout unit provided in each of the photoelectric conversion units and configured to read out the charge temporarily stored in the photoelectric conversion unit, a drive control unit that applies a drive pulse to the readout unit, and a shared holding unit shared by a plurality of the photoelectric conversion units and configured to hold the charge read out from the photoelectric conversion unit by the readout unit, the method, by the drive control unit, including: in a case where the charge is read out from a selected photoelectric conversion unit as a charge readout target out of the plurality of photoelectric conversion units sharing the shared holding unit to the shared holding unit, applying a first pulse to the readout unit that corresponds to the selected photoelectric conversion unit, and applying a second pulse having a polarity opposite to a polarity of the first pulse and having a pulse period overlapping with at least a portion of a pulse period of the first pulse, to a site coming into a capacitive coupling state with the shared holding unit.

An electronic device according to a second aspect of the present technology is an electronic device on which a solid-state imaging device is mounted, the solid-state imaging device including a photoelectric conversion unit that generates charge by photoelectric conversion corresponding to incident light and temporarily stores the generated charge, a readout unit provided in each of the photoelectric conversion units and configured to read out the charge temporarily stored in the photoelectric conversion unit, a drive control unit that applies a drive pulse to the readout unit, and a shared holding unit shared by a plurality of the photoelectric conversion units and configured to hold the charge read out from the photoelectric conversion unit by the readout unit, in which in a case where the charge is read out from a selected photoelectric conversion unit as a charge readout target out of the plurality of photoelectric conversion units sharing the shared holding unit to the shared holding unit, the drive control unit applies a first pulse to the readout unit that corresponds to the selected photoelectric conversion unit, and applies a second pulse having a polarity opposite to a polarity of the first pulse and having a pulse period overlapping with at least a portion of a pulse period of the first pulse, to a site coming into a capacitive coupling state with the shared holding unit.

In the first and second aspects of the present technology, in a case where the charge is read out from a selected photoelectric conversion unit as a charge readout target out of the plurality of photoelectric conversion units sharing the shared holding unit to the shared holding unit, a first pulse is applied to the readout unit that corresponds to the selected photoelectric conversion unit, and a second pulse having a polarity opposite to a polarity of the first pulse and having a pulse period overlapping with at least a portion of the pulse period of the first pulse is applied to a site coming into a capacitive coupling state with the shared holding unit.

### Effects of the Invention

According to the first and second aspects of the present technology, leakage of the charge from the photoelectric conversion unit to the shared holding unit can be suppressed.

Furthermore, according to the first and second aspects of the present technology, degradation of image quality can be suppressed.

### BRIEF DESCRIPTION OF DRAWINGS

FIG. 1 is an equivalent circuit diagram illustrating an example of a configuration of a solid-state imaging device in which FD is shared by two pixels.

FIG. 2 is a top view illustrating an example of a configuration of a solid-state imaging device in which FD is shared by four pixels arranged in a Bayer array.

FIG. 3 is a view illustrating a cross section corresponding to FIG. 1 and potential corresponding to the cross section.

FIG. 4 is a diagram illustrating control of a conventional applied voltage to a readout gate.

FIG. 5 is a diagram illustrating conventional photoelectric conversion characteristics in a case where FD is shared by four pixels.

FIG. 6 is a diagram illustrating control of an applied voltage to a readout gate according to a first embodiment.

FIG. 7 is a view illustrating potential corresponding to FIG. 6.

FIG. 8 is a diagram illustrating photoelectric conversion characteristics in a case where FD is shared by four pixels.

FIG. 9 is a diagram illustrating control of an applied voltage to a readout gate according to a second embodiment.

FIG. 10 is a diagram illustrating potential corresponding to FIG. 9.

FIG. 11 is a diagram illustrating a modification of the solid-state imaging device according to the present technology.

FIG. 12 is a diagram illustrating a modification of the solid-state imaging device according to the present technology.

FIG. 13 is a diagram illustrating a modification of the solid-state imaging device according to the present technology.

FIG. 14 is a diagram illustrating a modification of the solid-state imaging device according to the present technology.

FIG. 15 is a block diagram illustrating a schematic configuration example of an in-vivo information acquisition system.

FIG. 16 is a block diagram illustrating a schematic configuration example of a vehicle control system.

FIG. 17 is an view illustrating an example of installation positions of a vehicle exterior information detector and an imaging unit.

### MODE FOR CARRYING OUT THE INVENTION

Hereinafter, best modes (hereinafter referred to as embodiments) for implementing the present technology will be described in detail with reference to the drawings.

<1. First Embodiment>

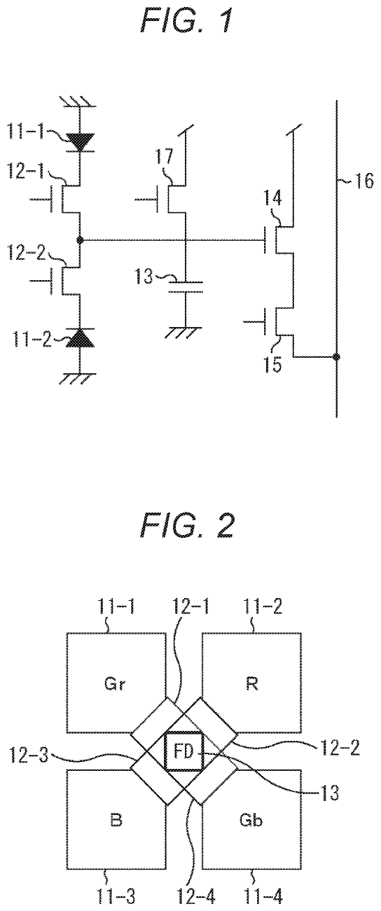

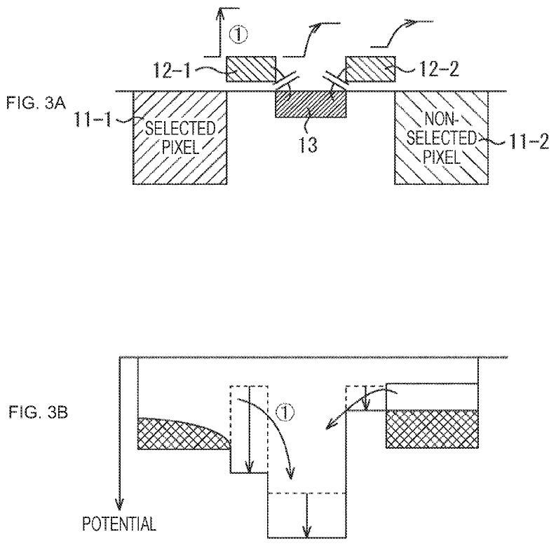

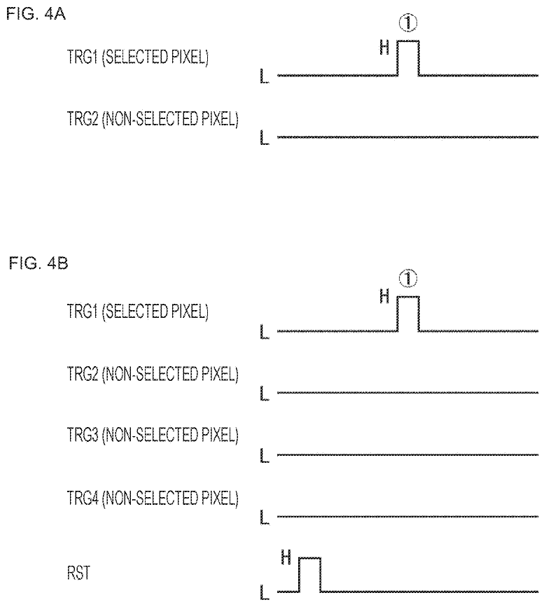

A solid-state imaging device according to a first embodiment of the present technology is configured in a similar manner as a conventional solid-state imaging device sharing FD with a plurality of pixels illustrated in FIG. 1 or 2. However, the applied voltage to the readout gate 11 for reading out the charge stored in each of PD 11 is different from the conventional case (FIG. 4). Furthermore, while FIG. 1 illustrates an exemplary case where the FD is shared by two pixels and FIG. 2 illustrates a case where the FD is shared by four pixels, the application of the present technology is not limited to these, and the present technology is applicable to every case of sharing the FD by two or more pixels.

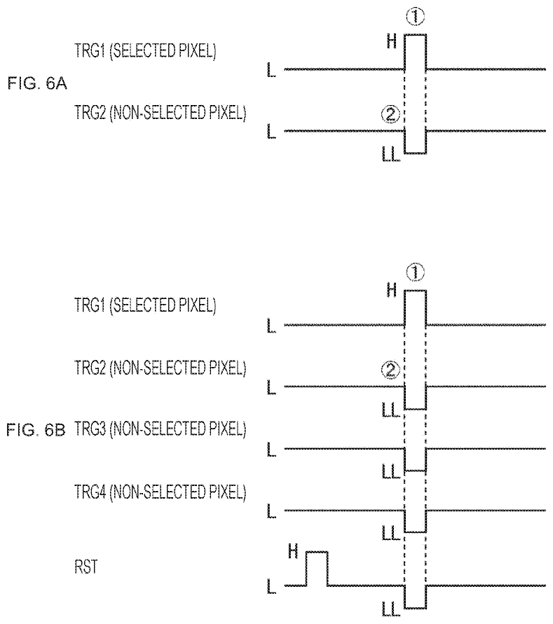

FIG. 6 is a diagram illustrating applied voltage to the readout gates 12 for a selected pixel on which charge stored in the PD 11 is to be read out and for a non-selected pixel on which charge stored in the PD 11 is not to be read out in the solid-state imaging device according to the first embodiment of the present technology. Note that in FIG. 6, TRG 1 represents the applied voltage to the readout gate 12 of the selected pixel, while TRG 2 to TRG 4 represent the applied voltage to the readout gate 12 of the non-selected pixel.

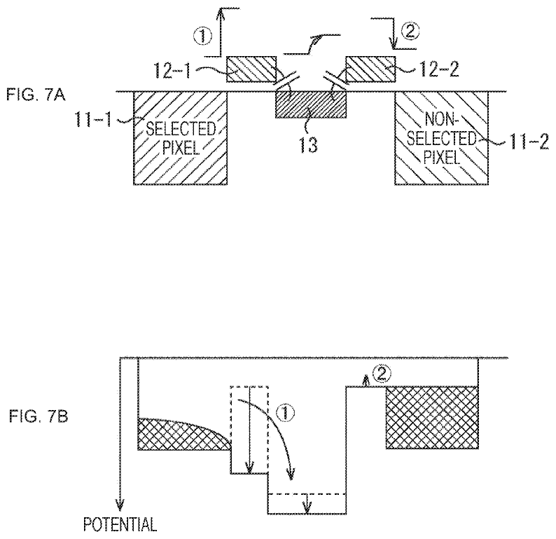

FIG. 7 illustrates: a cross section (A in FIG. 7) of the solid-state imaging device according to the first embodiment of the present technology; and potential (B of FIG. 7) corresponding to FIG. 6.

In a case where the charge is read out from the PD 11-1 of the selected pixel in the first embodiment, as illustrated in A of FIG. 6, the readout gate 12-1 of the selected pixel is turned on (applied voltage is switched from the L level to the H level). In accordance with this timing, a cancellation pulse is applied to the readout gate 12-2 of the non-selected pixel so as to change the voltage level from the L level to the LL level.

As illustrated in B of FIG. 7, this suppresses fluctuation of the readout gate 12-2 of non-selected pixel caused by the capacitive coupling occurring in the conventional case, making it possible to maintain the pinning state under the readout gate 12-2.

Since the pinning state under the readout gate 12-2 is kept, the potential below the readout gate 12-2 of the non-selected pixel would not increase, making it possible to suppress the leakage of saturated charge of the non-selected to the FD 13.

Note that in accordance with the timing of turning off the readout gate 12-1 of the selected pixel (applied voltage is switched from the H level to the L level), the applied voltage to the readout gate 12-2 of the non-selected pixel is switched from the LL level to the L level. This makes it possible to also suppress an influence (fluctuation of the readout gate 12-2 and the FD 13) caused by turning off the readout gate 12-1 of the selected pixel.

Furthermore, in a case where the solid-state imaging device shares the FD 13 by four pixels, as illustrated in B of FIG. 6, one of the four pixels is set as a selected pixel and the other three as non-selected pixels and then, it would be sufficient to control the applied voltage to each of the readout gates 12.

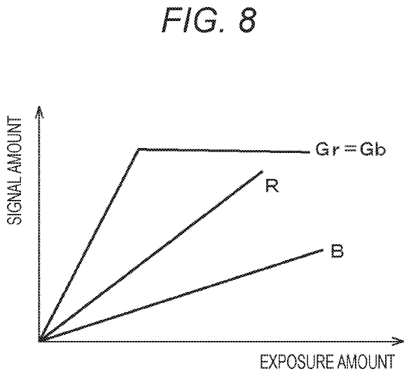

FIG. 8 illustrates the photoelectric conversion characteristics in a case where the applied voltage is controlled as illustrated in B of FIG. 6 in a case where the solid-state imaging device shares the FD 13 by four pixels of the Bayer array.

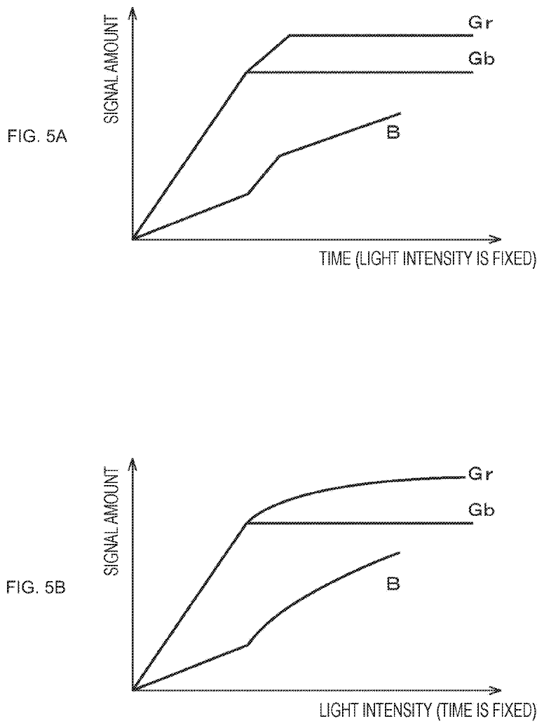

As is apparent from a comparison between FIG. 8 and FIG. 5, the signal values of Gr and Gb, which are supposed to match, become equal in the case of FIG. 8. Furthermore, since the signal values of B and R change linearly in accordance with the exposure amount, it is expected that deterioration of image quality can be suppressed as a result.

Meanwhile, regarding the LL level to be applied to the readout gate 12-2 of the non-selected pixel, depending on the gate oxide film thickness condition of the device, in a case where the H level of the voltage to be applied to the readout gate 12 at the time of readout is about 2.7V, for example, L bias in the exposure period is expected to be about −1.2V and LL bias is expected to be about −2V in normal situation.

Application of a lower negative voltage (for example, −3V) as the LL bias would increase the potential difference between the readout gate 12 to which the negative voltage is applied and the FD 13 and would cause a leaky scratch in the FD 13, while this can increase an effect of induction. Therefore, there is a limit to the LL bias.

Fortunately, however, application of the LL bias is not limited to the readout gate 12-2 of the non-selected pixel, and it is allowable to apply the voltage from an electrode adjacent to the shared FD 13. This can also obtain a similar fluctuation suppressing effect, and it is also possible to apply a cancellation pulse having an amplitude suppressed to a range capable of preventing FD leakage dispersedly from a plurality of electrodes adjacent to the FD 13. For example, in a case where the FD is shared by four pixels, the cancellation pulse may be applied from the readout gate 12 of three pixels other than the selected pixel. Furthermore, for example, a cancellation pulse having an amplitude suppressed within a range capable of preventing FD leakage may be applied from the reset gate 17 and the signal line 16. An example of application of a cancellation pulse to the reset gate 17 is as illustrated as RST in B of FIG. 6. Furthermore, these methods may be combined.

Here, a case of applying a cancellation pulse from the signal line 16 will be described. As illustrated in FIG. 1, the FD 13 is linked to the signal line 16 via the amplifier gate 14 and the selection gate 15. The amplifier gate 14 is in a state of capacitive coupling with the signal line 16-side diffusion layer. Since the selection gate 15 is turned on in a case where charge is read out from the PD 11 of the selected pixel, installing a control means for the signal line 16 and applying a cancellation pulse can suppress the fluctuation of the FD 13. Note that this control means can be configured with the following manner, for example. That is, since the signal line 16 is normally connected to a load MOS (not illustrated) which is a constant current source, a cancellation pulse applied to the signal line 16 can be generated by controlling the load MOS gate. Alternatively, a control transistor Tr. different from the load MOS may be connected to the signal line 16 to apply the cancellation pulse to the signal line 16 by the control transistor Tr.

<2. Second Embodiment>

Next, a second embodiment of the present technology will be described. Similarly to the first embodiment, a solid-state imaging device according to the second embodiment of the present technology is configured in a similar manner as a conventional solid-state imaging device sharing FD with a plurality of pixels illustrated in FIG. 1 or 2. However, the applied voltage to the readout gate 11 for reading out the charge stored in each of PD 11 is different from the conventional case (FIG. 4) and the case of the first embodiment (FIG. 6).

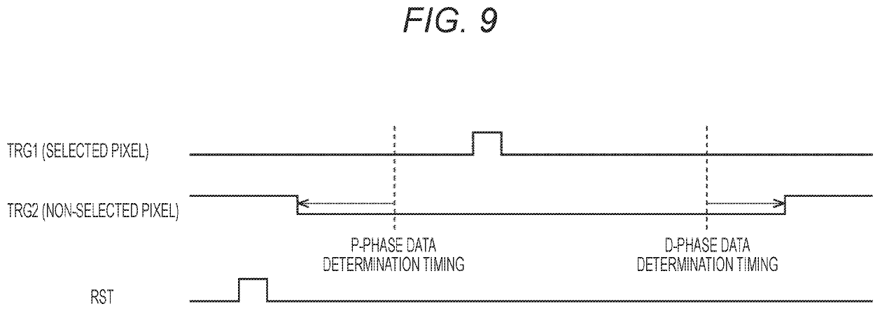

FIG. 9 is a diagram illustrating applied voltage to the readout gates 12 for a selected pixel on which charge stored in the PD 11 is to be read out and for a non-selected pixel on which charge stored in the PD 11 is not to be read out in the solid-state imaging device according to the second embodiment of the present technology. Note that in FIG. 9, TRG 1 represents the applied voltage to the readout gate 12 of the selected pixel, while TRG 2 represents the applied voltage to the readout gate 12 of the non-selected pixel.

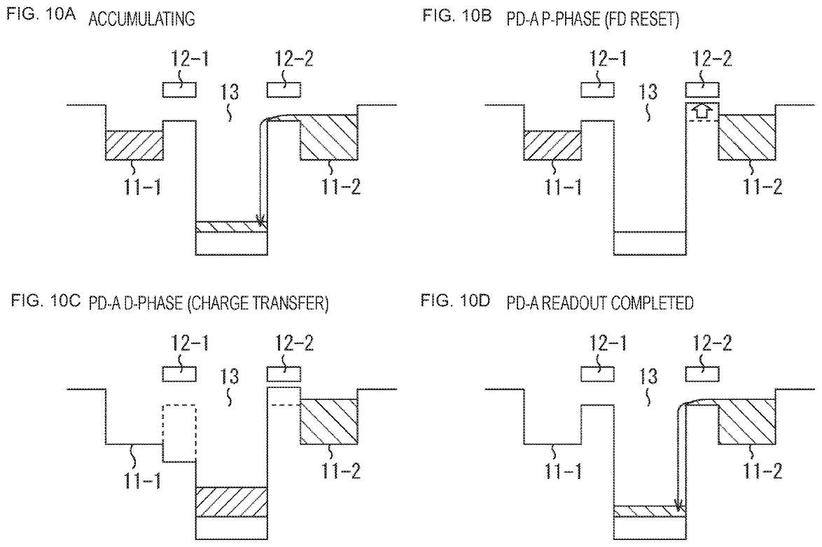

FIG. 10 illustrates the potentials of the PD 11-1, the readout gate 12-1, the FD 13, the readout gate 12-2, and the PD 11-2 corresponding to FIG. 9.

In the second embodiment, in order to store charge in each of PD 11 during the exposure period, an L bias of a negative voltage is applied to each of the readout gates 12 in a state where the overflow path is open. This allows excess charge to be discharged from the already saturated PD 11 (PD 11-2 in the drawing) to the FD 13 as illustrated in A of FIG. 10.

In a case where charge is read out from the PD 11-1 of the selected pixel after the exposure period, the reset gate 17 is turned on and FD 13 is reset in order to determine the P-phase data, as illustrated in FIG. 9. Next, applied voltage to the readout gate 12-2 of the non-selected pixel is controlled to a level lower than the L level at a timing before the readout gate 12-1 of the selected pixel is turned on (applied voltage is switched from the L level to the H level) and before the establishment timing of the P phase data. With this control, as illustrated in B of FIG. 10, the overflow path for PD 11-2 to FD 13 is closed (so as to increase an overflow margin).

Thereafter, the readout gate 12-1 of the selected pixel is turned on (applied voltage is switched from the L level to the H level). This allows the charge stored in the PD 11-1 to be transferred to the FD 13 via the readout gate 12-1, as illustrated in C of FIG. 10. Thereafter, the readout gate 12-1 of the selected pixel is turned off (applied voltage is switched from the H level to the L level), and then, the charge held in the FD 13 is transferred to the downstream and the D phase data is established.

After this D phase data establishment timing, the applied voltage to the readout gate 12-2 of the non-selected pixel is returned to L level. With this operation, as illustrated in D of FIG. 10, the overflow paths from the PD 11-2 to the FD 13 are returned to the normal state (open state).

With the control of the applied voltage to the readout gate 12 described above, it is possible to suppress the leakage of the charge stored in the non-selected pixels to the FD 13 at readout of the charge stored in the selected pixel to the FD 13, making it possible to ensure a proper signal amount of each of pixels, leading to suppressing of image degradation.

Note that in a case where the FD is shared by three or more pixels, the above-described control may be performed on the readout gates 12 of all the pixels except for the selected pixel, or on the readout gate 12 of some of the pixels other than the selected pixel.

Regarding the positive and negative (H or L) of the applied voltage in the above description, the above is an example in which PD is an n-type storage layer. Accordingly, in a case where PD is a p-type storage layer, it would be sufficient to reversely control positive and negative of the applied voltage.

<Modification>

Next, modifications of the above-described first and second embodiments will be described.

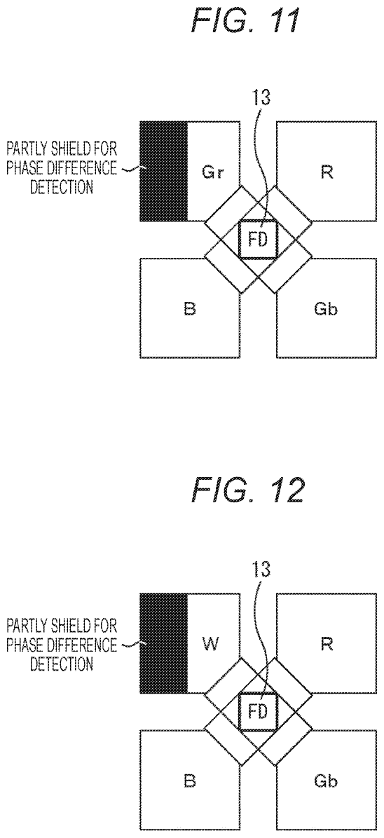

In a modification illustrated in FIG. 11, four pixels arranged in the Bayer array share the FD, and a receiving surface of one pixel (Gr in FIG. 11) of the four pixels is shielded so as to function also as a phase difference detection pixel used for image plane phase difference autofocus (AF) or the like. In this case, for example, charge stored in pixels is sequentially read out from a pixel having a larger exposure amount, that is, a pixel not shielded. However, the order of reading out the pixels is not limited to the example described above.

In a modification illustrated in FIG. 12, four pixels W, R, B, and G share the FD, and a receiving surface of one pixel (W in FIG. 11) of the four pixels is shielded so as to function also as a phase difference detection pixel used for image plane phase difference AF or the like. In this case, for example, charge stored in pixels is sequentially read out from a pixel having a larger exposure amount, that is, in the order of W, R, B, and G. However, the order of reading out the pixels is not limited to the example described above.

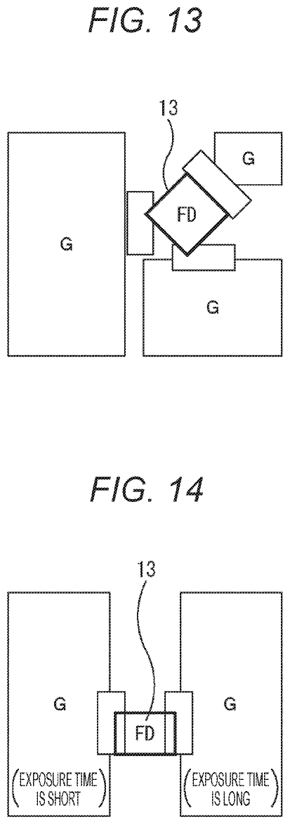

In a modification illustrated in FIG. 13, the FD is shared by three pixels individually using PDs with various sizes to produce mutually different exposure environment. In this case, for example, the stored charge is read in order from the pixel with the larger exposure amount, that is, from the pixel of larger PD size. However, the order of reading out the pixels is not limited to the example described above.

In a modification illustrated in FIG. 14, the FD is shared by two pixels individually using PDs with same size and various exposure time to produce mutually different exposure environment. In this case, for example, the stored charge is read in order from the pixel with the larger exposure amount, that is, from the pixel of longer exposure time. However, the order of reading out the pixels is not limited to the example described above.

The present technology can also be applied to modifications illustrated in FIGS. 11 to 14 and combinations of these.

<Example of Application to In-Vivo Information Acquisition System>

The technology according to the present disclosure (present technology) can be applied to various products. For example, the technology according to the present disclosure may be applied to an endoscopic surgery system.

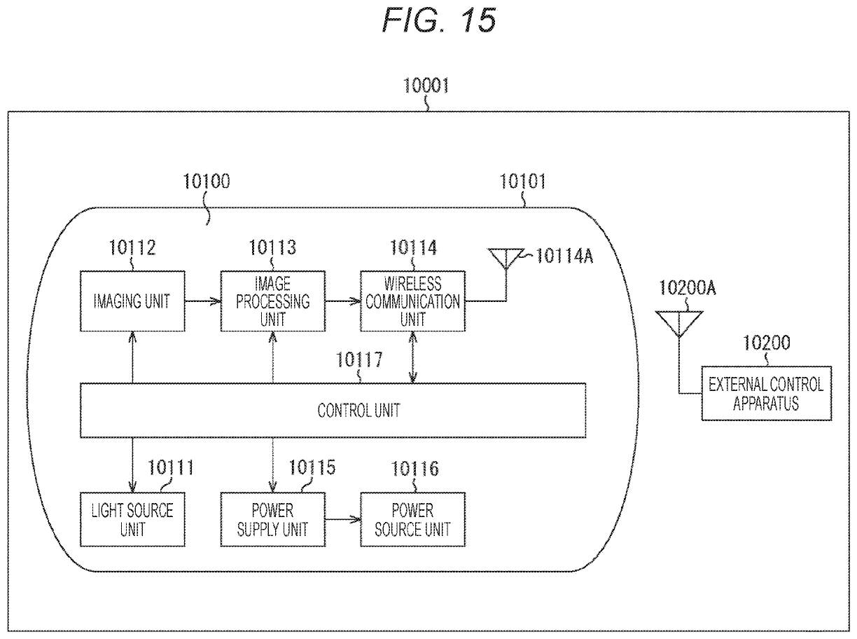

FIG. 15 is a block diagram illustrating an example of a schematic configuration of an in-vivo information acquisition system for a patient using a capsule endoscope to which the technique (the present technology) according to the present disclosure is applicable.

An in-vivo information acquisition system 10001 includes a capsule endoscope 10100 and an external control apparatus 10200.

The capsule endoscope 10100 is swallowed by a patient at the time of examination. The capsule endoscope 10100 has an imaging function and a wireless communication function, and sequentially captures images of internal organs such as the stomach and the intestine (hereinafter, referred to as in-vivo images) with a predetermined interval while moving inside the internal organs by peristaltic movement or the like, until being naturally discharged from the patient. Thereafter, the capsule endoscope 10100 sequentially wirelessly transmits information regarding the in-vivo images to the external control apparatus 10200, that is, a device outside the body.

The external control apparatus 10200 comprehensively controls operation of the in-vivo information acquisition system 10001. Furthermore, the external control apparatus 10200 receives information regarding the in-vivo images transmitted from the capsule endoscope 10100, and generates image data to display the in-vivo image on a display device (not illustrated) on the basis of the information regarding the received in-vivo image.

In this manner, the in-vivo information acquisition system 10001 can obtain in-vivo images obtained by imaging the inside of the patient's body at all times from time when the capsule endoscope 10100 is swallowed to time of discharge.

The configuration and functions of the capsule endoscope 10100 and the external control apparatus 10200 will be described in more detail.

The capsule endoscope 10100 has a capsule-shaped casing 10101. The casing 10101 includes a light source unit 10111, an imaging unit 10112, an image processing unit 10113, a wireless communication unit 10114, a power supply unit 10115, a power source unit 10116, and a control unit 10117.

The light source unit 10111 includes a light source such as a light emitting diode (LED), for example, and emits light to an imaging view field of the imaging unit 10112.

The imaging unit 10112 includes an optical system including an imaging element and a plurality of lenses provided in front of the imaging element. Reflected light (hereinafter referred to as observation light) of the light emitted to body tissue as an observation target is collected by the optical system and is incident on the imaging element. In the imaging unit 10112, the observation light incident on the imaging element is photoelectrically converted, and an image signal corresponding to the observation light is generated. The image signal generated by the imaging unit 10112 is supplied to the image processing unit 10113.

The image processing unit 10113 includes a processor such as a central processing unit (CPU) and a graphics processing unit (GPU), and performs various types of signal processing on the image signal generated by the imaging unit 10112. The image processing unit 10113 supplies the image signal that has undergone the signal processing as RAW data to the wireless communication unit 10114.

The wireless communication unit 10114 performs predetermined processing such as modulation processing on the image signal that has undergone signal processing by the image processing unit 10113, and transmits the processed image signal to the external control apparatus 10200 via an antenna 10114A. Furthermore, the wireless communication unit 10114 receives a control signal related to drive control of the capsule endoscope 10100 from the external control apparatus 10200 via the antenna antenna 10114A. The wireless communication unit 10114 supplies the control signal received from the external control apparatus 10200 to the control unit 10117.

The power supply unit 10115 includes: an antenna coil for power reception; a power regeneration circuit for regenerating power from the current generated in the antenna coil; a booster circuit, and the like. The power supply unit 10115 generates electric power using the principle of so-called non-contact charging.

The power source unit 10116 includes a secondary battery, and stores electric power generated by the power supply unit 10115. For the sake of avoiding complication of the drawing, FIG. 15 omits illustration of arrows or the like indicating destinations of power supply from the power source unit 10116. However, the power stored in the power source unit 10116 is transmitted to the light source unit 10111, the imaging unit 10112, the image processing unit 10113, the wireless communication unit 10114, and the control unit 10117, so as to be used for driving these units.

The control unit 10117 includes a processor such as a CPU and controls driving of the light source unit 10111, the imaging unit 10112, the image processing unit 10113, the wireless communication unit 10114, and the power supply unit 10115 in accordance with a control signal transmitted from the external control apparatus 10200.

The external control apparatus 10200 includes a processor such as a CPU and GPU, or a microcomputer, a control board or the like including a processor and storage elements such as memory in combination. The external control apparatus 10200 transmits a control signal to the control unit 10117 of the capsule endoscope 10100 via an antenna 10200A and thereby controls operation of the capsule endoscope 10100. In the capsule endoscope 10100, for example, the light emission condition toward an observation target in the light source unit 10111 can be changed by a control signal from the external control apparatus 10200. Furthermore, imaging conditions (for example, frame rate in the imaging unit 10112, the exposure value, etc.) can be changed by the control signal from the external control apparatus 10200. Furthermore, the control signal from the external control apparatus 10200 may be used to change the processing details in the image processing unit 10113 and image signal transmission condition (for example, transmission interval, the number of images to be transmitted, etc.) of the wireless communication unit 10114.

Furthermore, the external control apparatus 10200 performs various types of image processing on the image signal transmitted from the capsule endoscope 10100, and generates image data for displaying the captured in-vivo image on the display device. Examples of the image processing include various types of signal processing such as developing processing (demosaicing), high image quality processing (band enhancement processing, super resolution processing, noise reduction (NR) processing and/or camera shake correction processing, etc.), and/or enlargement processing (electronic zoom processing), for example. The external control apparatus 10200 controls driving of the display device and displays captured in-vivo images on the basis of the generated image data. Alternatively, the external control apparatus 10200 may control the recording apparatus (not illustrated) to record the generated image data, or may control the printing apparatus (not illustrated) to print out the generated image data.

An example of the in-vivo information acquisition system to which the technology according to the present disclosure can be applied has been described above. The technology according to the present disclosure can be suitably applied to the imaging unit 10112 out of the above-described configuration.

<Application Example to Mobile Body>

The technology according to the present disclosure (present technology) can be applied to various products. For example, the technology according to the present disclosure may be implemented as an apparatus mounted on any type of mobile body such as an automobile, an electric vehicle, a hybrid electric vehicle, a motorcycle, bicycle, personal mobility, airplane, drone, ship, and robot.

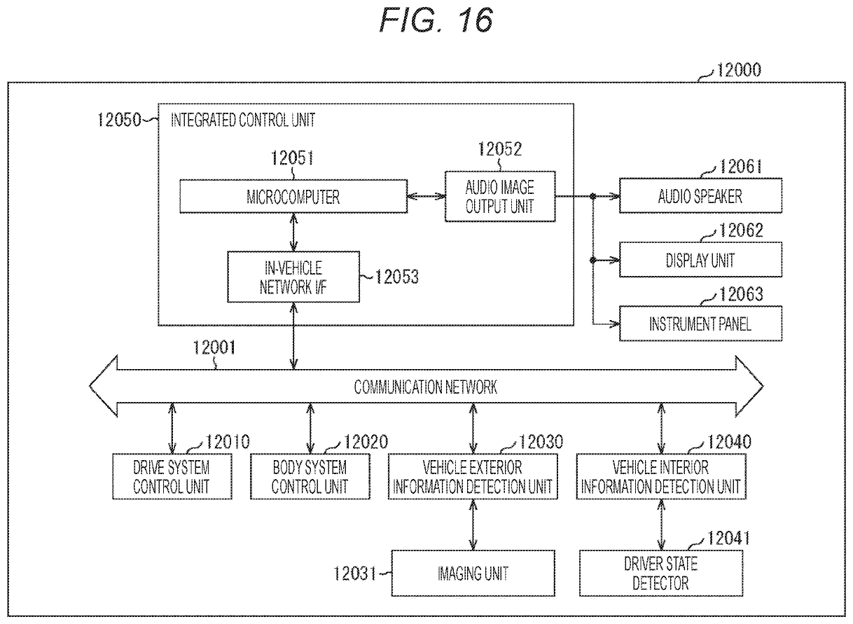

FIG. 16 is a block diagram illustrating an example of a schematic configuration of a vehicle control system as an example of a mobile body control system to which the technology according to the present disclosure can be applied.

A vehicle control system 12000 includes a plurality of electronic control units connected via a communication network 12001. In the example illustrated in FIG. 16, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, an audio image output unit 12052, and an in-vehicle network interface (I/F) 12053 are illustrated.

The drive system control unit 12010 controls operation of the apparatus related to the drive system of the vehicle in accordance with various programs. For example, the drive system control unit 12010 functions as a control apparatus of a driving force generation apparatus that generates a driving force of a vehicle such as an internal combustion engine or a driving motor, a driving force transmission mechanism that transmits a driving force to the wheels, a steering mechanism that adjusts steering angle of the vehicle, a braking apparatus that generates a braking force of the vehicle, or the like.

The body system control unit 12020 controls operation of various devices equipped on the vehicle body in accordance with various programs. For example, the body system control unit 12020 functions as a control apparatus for a keyless entry system, a smart key system, a power window device, or various lamps such as a head lamp, a back lamp, a brake lamp, a turn signal lamp, or a fog lamp. In this case, the body system control unit 12020 can receive inputs of a radio wave transmitted from a portable device that substitutes a key, or a signal of various switches. The body system control unit 12020 receives inputs of these radio waves or signals and controls the door lock device, the power window device, the lamp, etc. of the vehicle.

The vehicle exterior information detection unit 12030 detects information outside the vehicle equipped with the vehicle control system 12000. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing on objects such as a person, a car, an obstacle, a sign, and a character on a road surface on the basis of the received image.

The imaging unit 12031 is an optical sensor that receives light and outputs an electric signal corresponding to the amount of light received. The imaging unit 12031 can output an electric signal as an image or output it as distance measurement information. Furthermore, the light received by the imaging unit 12031 may be visible light or invisible light such as infrared light.

The vehicle interior information detection unit 12040 detects information inside the vehicle. The vehicle interior information detection unit 12040 is connected with a driver state detector 12041 that detects the state of the driver, for example. The driver state detector 12041 may include a camera that images the driver, for example. The vehicle interior information detection unit 12040 may calculate the degree of fatigue or degree of concentration of the driver or may determine whether or not the driver is dozing off on the basis of the detection information input from the driver state detector 12041.

The microcomputer 12051 can calculate a control target value of the driving force generation apparatus, the steering mechanism, or the braking apparatus on the basis of vehicle external/internal information obtained by the vehicle exterior information detection unit 12030 or the vehicle interior information detection unit 12040, and can output a control command to the drive system control unit 12010. For example, the microcomputer 12051 can perform cooperative control for the purpose of achieving a function of an advanced driver assistance system (ADAS) including collision avoidance or impact mitigation of vehicles, follow-up running based on an inter-vehicle distance, cruise control, vehicle collision warning, vehicle lane departure warning, or the like.

Furthermore, it is allowable such that the microcomputer 12051 controls the driving force generation apparatus, the steering mechanism, the braking apparatus, or the like, on the basis of the information regarding the surroundings of the vehicle obtained by the vehicle exterior information detection unit 12030 or the vehicle interior information detection unit 12040, thereby performing cooperative control for the purpose of automatic driving or the like of performing autonomous traveling without depending on the operation of the driver.

Furthermore, the microcomputer 12051 can output a control command to the body system control unit 12020 on the basis of the vehicle exterior information obtained by the vehicle exterior information detection unit 12030. For example, the microcomputer 12051 can control the head lamp in accordance with the position of the preceding vehicle or the oncoming vehicle sensed by the vehicle exterior information detection unit 12030, and thereby can perform cooperative control aiming at antiglare such as switching the high beam to low beam.

The audio image output unit 12052 transmits an output signal in the form of at least one of audio or image to an output apparatus capable of visually or audibly notifying the occupant of the vehicle or the outside of the vehicle of information. In the example of FIG. 16, an audio speaker 12061, a display unit 12062, and an instrument panel 12063 are illustrated as exemplary output apparatuses. The display unit 12062 may include at least one of an on-board display or a head-up display, for example.

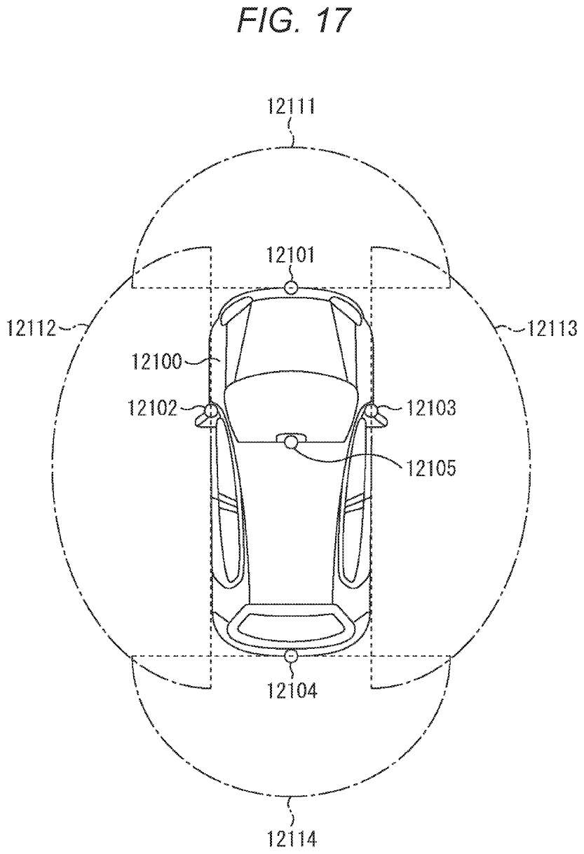

FIG. 17 is a view illustrating an example of an installation location of the imaging unit 12031.

In FIG. 17, the imaging unit 12031 includes imaging units 12101, 12102, 12103, 12104, and 12105.

For example, the imaging units 12101, 12102, 12103, 12104, and 12105 are installed in at least one of positions on a vehicle 12100, including a front nose, a side mirror, a rear bumper, a back door, an upper portion of windshield in a passenger compartment, or the like. The imaging unit 12101 provided at a front nose and the imaging unit 12105 provided on the upper portion of the windshield in the passenger compartment mainly obtain an image ahead of the vehicle 12100. The imaging units 12102 and 12103 provided at the side mirror mainly obtain images of the side of the vehicle 12100. The imaging unit 12104 provided in the rear bumper or the back door mainly obtains an image behind the vehicle 12100. The imaging unit 12105 provided at an upper portion of the windshield in the passenger compartment is mainly used for detecting a preceding vehicle, a pedestrian, an obstacle, a traffic signal, a traffic sign, a lane, or the like.

Note that FIG. 17 illustrates an example of photographing ranges of the imaging units 12101 to 12104. An imaging range 12111 represents an imaging range of the imaging unit 12101 provided at the front nose, imaging ranges 12112 and 12113 represent imaging ranges of the imaging units 12102 and 12103 provided at the side mirror, and an imaging range 12114 represents an imaging range of the imaging unit 12104 provided at the rear bumper or the back door. For example, the image data captured by the imaging units 12101 to 12104 are overlapped, thereby producing an overhead view image of the vehicle 12100 viewed from above.

At least one of the imaging units 12101 to 12104 may have a function of obtaining distance information. For example, at least one of the imaging units 12101 to 12104 may be a stereo camera including a plurality of imaging elements, or may be an imaging element having pixels for phase difference detection.

For example, the microcomputer 12051 can calculate a distance to each of three-dimensional objects in the imaging ranges 12111 to 12114 and a temporal change (relative speed with respect to the vehicle 12100) of the distance on the basis of the distance information obtained from the imaging units 12101 to 12104, and thereby can extract a three-dimensional object traveling at a predetermined speed (for example, 0 km/h or more) in substantially the same direction as the vehicle 12100 being the nearest three-dimensional object on the traveling path of the vehicle 12100, as a preceding vehicle. Furthermore, the microcomputer 12051 can set an inter-vehicle distance to be ensured in front of the preceding vehicle in advance, and can perform automatic brake control (including follow-up stop control), automatic acceleration control (including follow-up start control), or the like. In this manner, it is possible to perform cooperative control aiming at automatic driving or the like of achieving autonomous traveling without depending on the operation of the driver.

For example, on the basis of the distance information obtained from the imaging units 12101 to 12104, the microcomputer 12051 can extract the three-dimensional object data regarding the three-dimensional object with classification into three-dimensional objects such as a two-wheeled vehicle, a regular vehicle, a large vehicle, a pedestrian, and other three-dimensional objects such as a utility pole, so as to be used for automatic avoidance of obstacles. For example, the microcomputer 12051 discriminates an obstacle in the vicinity of the vehicle 12100 as an obstacle having visibility to the driver of the vehicle 12100 from an obstacle having low visibility to the driver. Next, the microcomputer 12051 determines a collision risk indicating the risk of collision with each of obstacles. When the collision risk is a set value or more and there is a possibility of collision, the microcomputer 12051 can output an alarm to the driver via the audio speaker 12061 and the display unit 12062, and can perform forced deceleration and avoidance steering via the drive system control unit 12010, thereby achieving driving assistance for collision avoidance.

At least one of the imaging units 12101 to 12104 may be an infrared camera for detecting infrared rays. For example, the microcomputer 12051 can recognize a pedestrian by determining whether or not a pedestrian exists in the captured images of the imaging units 12101 to 12104. Such pedestrian recognition is performed, for example, by a procedure of extracting feature points in a captured image of the imaging units 12101 to 12104 as an infrared camera, and by a procedure of performing pattern matching processing on a series of feature points indicating the contour of the object to discriminate whether or not it is a pedestrian. When the microcomputer 12051 determines that a pedestrian is present in the captured images of the imaging units 12101 to 12104 and recognizes a pedestrian, the audio image output unit 12052 controls the display unit 12062 to perform superimposing display of a rectangular contour line for emphasis to the recognized pedestrian. Furthermore, the audio image output unit 12052 may control the display unit 12062 to display icons or the like indicating pedestrians at desired positions.

Hereinabove, an example of the vehicle control system to which the technology according to the present disclosure can be applied has been described. The technology according to the present disclosure can be suitably applied to the imaging unit 12031 out of the above-described configuration.

Embodiments of the present technology are not limited to the above-described embodiments but can be modified in a variety of ways without departing from the scope of the present technology.

The present technology may also be configured as follows.

(1)

A solid-state imaging device including:

a photoelectric conversion unit that generates charge by photoelectric conversion corresponding to incident light and temporarily stores the generated charge;

a readout unit provided in each of the photoelectric conversion units and configured to read out the charge temporarily stored in the photoelectric conversion unit;

a drive control unit that applies a drive pulse to the readout unit; and

a shared holding unit shared by a plurality of the photoelectric conversion units and configured to hold the charge read out from the photoelectric conversion unit by the readout unit,

in which in a case where the charge is read out from a selected photoelectric conversion unit as a charge readout target out of the plurality of photoelectric conversion units sharing the shared holding unit to the shared holding unit,

the drive control unit

applies a first pulse to the readout unit that corresponds to the selected photoelectric conversion unit, and

applies a second pulse having a polarity opposite to a polarity of the first pulse and having a pulse period overlapping with at least a portion of a pulse period of the first pulse, to a site coming into a capacitive coupling state with the shared holding unit.

(2)

The solid-state imaging device according to (1), further including:

a reset unit that sets the shared holding unit to a predetermined voltage; and

a signal line that transmits signal charge of the shared holding unit as a signal voltage,

in which in a case where the charge is read out from the selected photoelectric conversion unit out of the plurality of photoelectric conversion units sharing the shared holding unit to the shared holding unit,

the drive control unit

applies the first pulse to the readout unit that corresponds to the selected photoelectric conversion unit, and

applies the second pulse to at least one of the readout unit that corresponds to the one except for the selected photoelectric conversion unit out of the plurality of photoelectric conversion units sharing the shared holding unit, the reset unit, or the signal line.

(3)

The solid-state imaging device according to (1) or (2),

in which the second pulse has a polarity opposite to a polarity of the first pulse and has a pulse period matching a pulse period of the first pulse.

(4)

The solid-state imaging device according to (1) or (2),

in which the second pulse has a polarity opposite to a polarity of the first pulse and has a pulse period including a pulse period of the first pulse.

(5)

The solid-state imaging device according to (1) or (2),

in which the second pulse has a polarity opposite to a polarity of the first pulse and has a pulse period including a period from a P-phase data determination timing to a D-phase data determination timing.

(6)

The solid-state imaging device according to any of (1) to (5),

in which the shared holding unit is shared by a plurality of photoelectric conversion units having different exposure environments.

(7)

The solid-state imaging device according to (6),

in which in a case of the plurality of photoelectric conversion units having different exposure environments, the charge is sequentially read out to the shared holding unit in order from the photoelectric conversion unit having the greater exposure amount.

(8)

A method of driving a solid-state imaging device including

a photoelectric conversion unit that generates charge by photoelectric conversion corresponding to incident light and temporarily stores the generated charge,

a readout unit provided in each of the photoelectric conversion units and configured to read out the charge temporarily stored in the photoelectric conversion unit,

a drive control unit that applies a drive pulse to the readout unit, and

a shared holding unit shared by a plurality of the photoelectric conversion units and configured to hold the charge read out from the photoelectric conversion unit by the readout unit,

the method, by the drive control unit, including:

in a case where the charge is read out from a selected photoelectric conversion unit as a charge readout target out of the plurality of photoelectric conversion units sharing the shared holding unit to the shared holding unit,

applying a first pulse to the readout unit that corresponds to the selected photoelectric conversion unit; and

applying a second pulse having a polarity opposite to a polarity of the first pulse and having a pulse period overlapping with at least a portion of a pulse period of the first pulse, to a site coming into a capacitive coupling state with the shared holding unit.

(9)

An electronic device on which a solid-state imaging device is mounted,

the solid-state imaging device including

a photoelectric conversion unit that generates charge by photoelectric conversion corresponding to incident light and temporarily stores the generated charge,

a readout unit provided in each of the photoelectric conversion units and configured to read out the charge temporarily stored in the photoelectric conversion unit,

a drive control unit that applies a drive pulse to the readout unit, and

a shared holding unit shared by a plurality of the photoelectric conversion units and configured to hold the charge read out from the photoelectric conversion unit by the readout unit,

in which in a case where the charge is read out from a selected photoelectric conversion unit as a charge readout target out of the plurality of photoelectric conversion units sharing the shared holding unit to the shared holding unit, the drive control unit

applies a first pulse to the readout unit that corresponds to the selected photoelectric conversion unit, and

applies a second pulse having a polarity opposite to a polarity of the first pulse and having a pulse period overlapping with at least a portion of a pulse period of the first pulse, to a site coming into a capacitive coupling state with the shared holding unit.

### REFERENCE SIGNS LIST

11 PD

12 Readout gate

13 FD

14 Amplifier gate

15 Selection gate

16 Signal line

17 Reset gate

1. A solid-state imaging device comprising:
a photoelectric conversion unit that generates charge by photoelectric conversion corresponding to incident light and temporarily stores the generated charge;
a readout unit provided in each of the photoelectric conversion units and configured to read out the charge temporarily stored in the photoelectric conversion unit;
a drive control unit that applies a drive pulse to the readout unit; and
a shared holding unit shared by a plurality of the photoelectric conversion units and configured to hold the charge read out from the photoelectric conversion unit by the readout unit,
wherein in a case where the charge is read out from a selected photoelectric conversion unit as a charge readout target out of the plurality of photoelectric conversion units sharing the shared holding unit to the shared holding unit,
the drive control unit
applies a first pulse to the readout unit that corresponds to the selected photoelectric conversion unit, and
applies a second pulse having a polarity opposite to a polarity of the first pulse and having a pulse period overlapping with at least a portion of a pulse period of the first pulse, to a site coming into a capacitive coupling state with the shared holding unit.

2. The solid-state imaging device according to claim 1, further comprising:
a reset unit that sets the shared holding unit to a predetermined voltage; and
a signal line that transmits signal charge of the shared holding unit as a signal voltage,
wherein in a case where the charge is read out from the selected photoelectric conversion unit out of the plurality of photoelectric conversion units sharing the shared holding unit to the shared holding unit,
the drive control unit
applies the first pulse to the readout unit that corresponds to the selected photoelectric conversion unit, and
applies the second pulse to at least one of the readout unit that corresponds to the one except for the selected photoelectric conversion unit out of the plurality of photoelectric conversion units sharing the shared holding unit, the reset unit, or the signal line.

3. The solid-state imaging device according to claim 1,
wherein the second pulse has a polarity opposite to a polarity of the first pulse and has a pulse period matching a pulse period of the first pulse.

4. The solid-state imaging device according to claim 1,
wherein the second pulse has a polarity opposite to a polarity of the first pulse and has a pulse period including a pulse period of the first pulse.

5. The solid-state imaging device according to claim 1,
wherein the second pulse has a polarity opposite to a polarity of the first pulse and has a pulse period including a period from a P-phase data determination timing to a D-phase data determination timing.

6. The solid-state imaging device according to claim 1,
wherein the shared holding unit is shared by a plurality of photoelectric conversion units having different exposure environments.

7. The solid-state imaging device according to claim 6,
wherein in a case of the plurality of photoelectric conversion units having different exposure environments,
the charge is sequentially read out to the shared holding unit in order from the photoelectric conversion unit having the greatest exposure amount.

8. A method of driving a solid-state imaging device including
a photoelectric conversion unit that generates charge by photoelectric conversion corresponding to incident light and temporarily stores the generated charge,
a readout unit provided in each of the photoelectric conversion units and configured to read out the charge temporarily stored in the photoelectric conversion unit,
a drive control unit that applies a drive pulse to the readout unit, and
a shared holding unit shared by a plurality of the photoelectric conversion units and configured to hold the charge read out from the photoelectric conversion unit by the readout unit,
the method, by the drive control unit, comprising:
in a case where the charge is read out from a selected photoelectric conversion unit as a charge readout target out of the plurality of photoelectric conversion units sharing the shared holding unit to the shared holding unit,
applying a first pulse to the readout unit that corresponds to the selected photoelectric conversion unit; and
applying a second pulse having a polarity opposite to a polarity of the first pulse and having a pulse period overlapping with at least a portion of a pulse period of the first pulse, to a site coming into a capacitive coupling state with the shared holding unit.

9. An electronic device on which a solid-state imaging device is mounted,
the solid-state imaging device including
a photoelectric conversion unit that generates charge by photoelectric conversion corresponding to incident light and temporarily stores the generated charge,
a readout unit provided in each of the photoelectric conversion units and configured to read out the charge temporarily stored in the photoelectric conversion unit,
a drive control unit that applies a drive pulse to the readout unit, and
a shared holding unit shared by a plurality of the photoelectric conversion units and configured to hold the charge read out from the photoelectric conversion unit by the readout unit,
wherein in a case where the charge is read out from a selected photoelectric conversion unit as a charge readout target out of the plurality of photoelectric conversion units sharing the shared holding unit to the shared holding unit, the drive control unit
applies a first pulse to the readout unit that corresponds to the selected photoelectric conversion unit, and
applies a second pulse having a polarity opposite to a polarity of the first pulse and having a pulse period overlapping with at least a portion of a pulse period of the first pulse, to a site coming into a capacitive coupling state with the shared holding unit.
